(19) United States
(12) Patent Application Publication
(10) Pub. No.: US 2013/0312994 A1
(43) Pub. Date: Nov. 28, 2013

(54) APPARATUS AND METHOD FOR CONNECTING SENSING LEADS TO LARGE CABLES

(71) Applicant: Steven David Keuss, Brentwood, MO (US)

(72) Inventor: Steven David Keuss, Brentwood, MO (US)

(73) Assignee: ASSOCIATED EQUIPMENT CORPORATION, St. Louis, MO (US)

(21) Appl. No.: 13/480,282

(22) Filed: May 24, 2012

(51) Int. Cl. H05K 5/00; H01R 43/00

(52) U.S. Cl. 174/50; 156/49

(57) ABSTRACT

A splice enclosure is made from a non-conductive material. The splice enclosure has an arcuate groove configured to accept a cable, a first hole configured to hold a conductive piercing device therein, and a second hole configured to accept a thin lead having a stripped end. The stripped end of the thin lead can be compressively held over the conductive piercing device to create an electrical contact between the cable and the thin lead.

### BACKGROUND OF THE INVENTION

This invention relates generally to electrical connections, and more particularly to methods and apparatus for electrically splicing wires of significantly different diameters.

It is sometimes necessary to connect a very small gage wire (such as AWG 24 to 18 [0.5105 mm to 1.024 mm]) to a much larger electric cable (e.g., AWG 4 [5.189 mm]). These occasions arise, for example, when connecting a small sensor wire or lead to a larger, current carrying wire. When the sensor lead is used in conjunction with a low voltage circuit, insulation and isolation are often not of paramount concern. Utility companies have methods and apparatus to splice a feeder line to a high power line, but the splicing apparatus and methods are quite specialized. In addition, the splices require special tools and knowledge to install, and may be cost prohibitive for many uses.

It would thus be desirable to provide methods and apparatus for splicing a small gage wire to a much larger cable that can be used by an individual having no knowledge or skills in dealing with electrical wiring. In addition, it would be desirable to provide such methods and apparatus that permit the installation of splices by a lay person with readily available tools, and to provide a splice apparatus that is very cost effective even if manufactured on a small scale.

### BRIEF DESCRIPTION OF THE INVENTION

In one aspect, some configurations of the present invention therefore provide a splice enclosure made from a non-conductive material. The splice enclosure has an arcuate groove configured to accept a cable, a first hole configured to hold a conductive piercing device therein, and a second hole configured to accept a thin lead having a stripped end. The stripped end of the thin lead can be compressively held over the conductive piercing device to create an electrical contact between the cable and the thin lead.

In another aspect, some configurations of the present invention provide a method for electrically splicing a cable to a thin lead. The method includes attaching a cable to an enclosure having a conductive piercing device and stripping a length of insulation from an end of the thin lead to expose a portion of thin conductive wire. The method further includes inserting the stripped end of the thin lead into a hole in the enclosure so that at least a portion of the thin conductive wire is directly over the conductive piercing device internal to the enclosure, and compressively securing the thin conductive wire to the conductive piercing device.

It will thus be appreciated that some embodiments of the present invention provide methods and apparatus for splicing a small gage wire to a much larger cable that can be used by an individual having no knowledge or skills in dealing with electrical wiring. In addition, it will be appreciated that some embodiments of the present invention provide methods and apparatus that permit the installation of splices by a lay person with readily available tools, such as a screwdriver. Moreover, some embodiments of the present invention provide a splice apparatus that can include parts molded out of plastic or hard rubber (or another inexpensive insulating material) and other very inexpensive metal parts, such as screws and bushings. This, some embodiments of the present invention are very cost effective even if manufactured on a small scale.

### BRIEF DESCRIPTION OF THE DRAWINGS

FIG. 1 is an isometric view of an embodiment of a splice apparatus showing how a splice is made using the apparatus.

FIG. 2 is a cross-sectional view of the embodiment of FIG. 1 along the line 2-2 in FIG. 1.

FIG. 3 is an isometric view of an embodiment of a splice apparatus shown wrapped in an insulating tape.

FIG. 4 is an isometric view of the bottom of an embodiment of a splice apparatus showing ridges that are used in some embodiments to help prevent liquids and foreign materials from contacting the actual electrical contact made by a splice.

FIG. 5 is a left side orthographic projection, with hidden lines, of one embodiment of an enclosure of a splice apparatus.

FIG. 6 is a front side orthographic projection, with hidden lines, of the embodiment of the enclosure of a splice apparatus shown in FIG. 5.

FIG. 7 is a left side orthographic projection, with hidden lines, of one embodiment of an enclosure of a splice apparatus.

FIG. 8 is a front side orthographic projection, with hidden lines, of the embodiment of the enclosure of a splice apparatus shown in FIG. 7.

FIG. 9 is a left side orthographic projection, with hidden lines, of one embodiment of an enclosure of a splice apparatus.

FIG. 10 is a front side orthographic projection, with hidden lines, of the embodiment of the enclosure of a splice apparatus shown in FIG. 9.

FIG. 11 is a left side orthographic projection, with hidden lines, of one embodiment of an enclosure of a splice apparatus.

FIG. 12 is a front side orthographic projection, with hidden lines, of the embodiment of the enclosure of a splice apparatus shown in FIG. 11.

FIG. 13 is a left side orthographic projection, with hidden lines, of one embodiment of an enclosure of a splice apparatus.

FIG. 14 is a front side orthographic projection, with hidden lines, of the embodiment of the enclosure of a splice apparatus shown in FIG. 13.

FIG. 15 is a left side orthographic projection, with hidden lines, of one embodiment of an enclosure of a splice apparatus.

FIG. 16 is a front side orthographic projection, with hidden lines, of the embodiment of the enclosure of a splice apparatus shown in FIG. 15.

FIG. 17 is an isometric view of a hinged splice apparatus.

FIG. 18 is a left side view (without hidden lines) of a splice apparatus having an enclosure and a cover piece, shown in relationship to one another but as yet unattached.

The foregoing summary, as well as the following detailed description of certain embodiments of the present invention, will be better understood when read in conjunction with the appended drawings. To the extent that the figures illustrate diagrams of the functional blocks of various embodiments, the functional blocks are not necessarily indicative of the division between hardware circuitry.

### DETAILED DESCRIPTION OF THE INVENTION

As used herein, an element or step recited in the singular and proceeded with the word “a” or “an” should be understood as not excluding plural said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

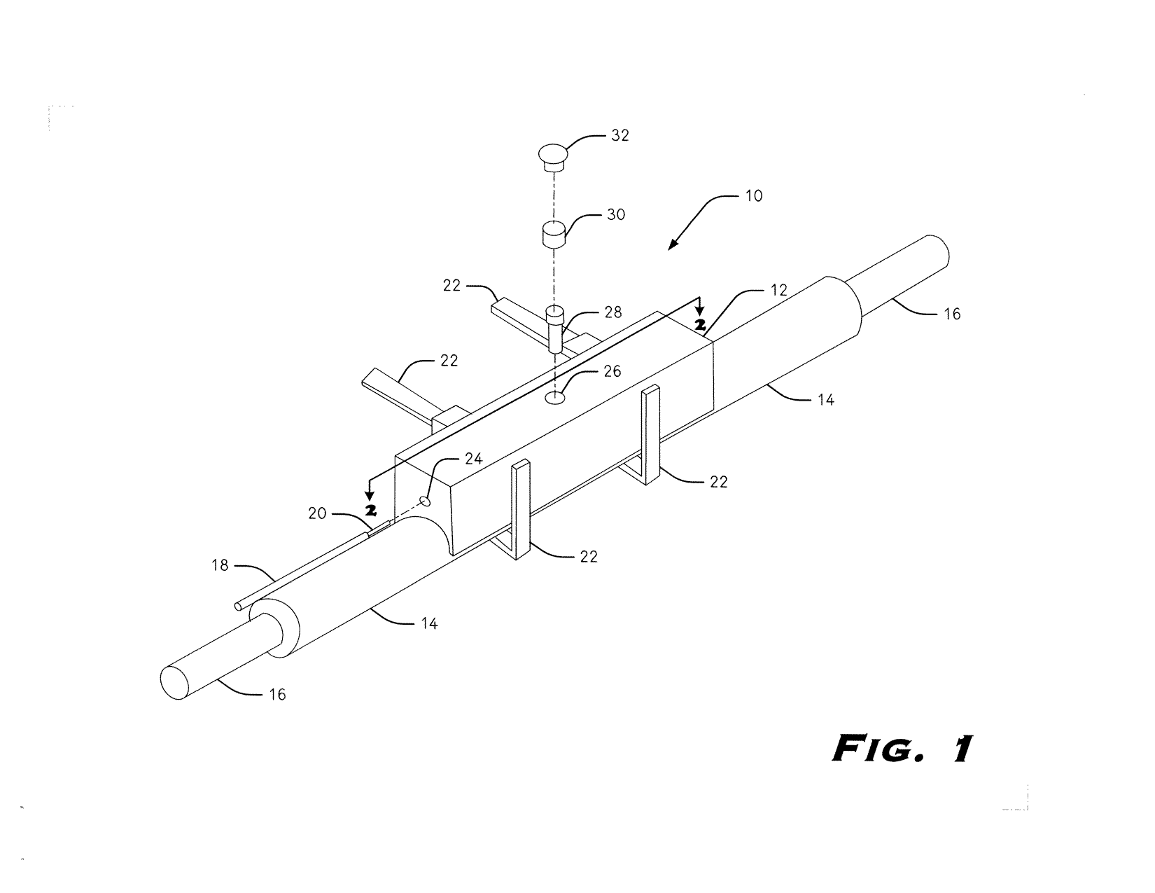

In some embodiments and referring to FIG. 1, a splice 10 comprises a non-conductive (e.g., plastic or hard rubber) enclosure 12 configured to hold a cable 14 housing a thick conductive wire 16 in place. (The insulation around thick conductive wire 16 is shown as being removed close to enclosure 12 in FIG. 1 for illustrative purposes only. The length of the insulation around thick conductive wire 16 beyond the ends of enclosure 12 is not specified, nor is it material to the practicing of the present invention.) Enclosure 12 is attached to cable 14 using cable ties 22, which, in the illustrated embodiment, pass through holes in enclosure 12 to remain spaced apart and thus better grip cable 14. A thin lead 18 enclosing a thin conductive wire 20 is inserted into a first hole 24 of enclosure 12. A portion of the insulation of thin lead 18 is stripped of so that thin conductive wire 20 can be placed directly under hole 26 of enclosure 12. Hole 26 in the illustrated embodiment is generally perpendicular to hole 24. Thin lead 18 is “thin” in the sense that it has a smaller diameter than cable 14, and may have a substantially smaller diameter.

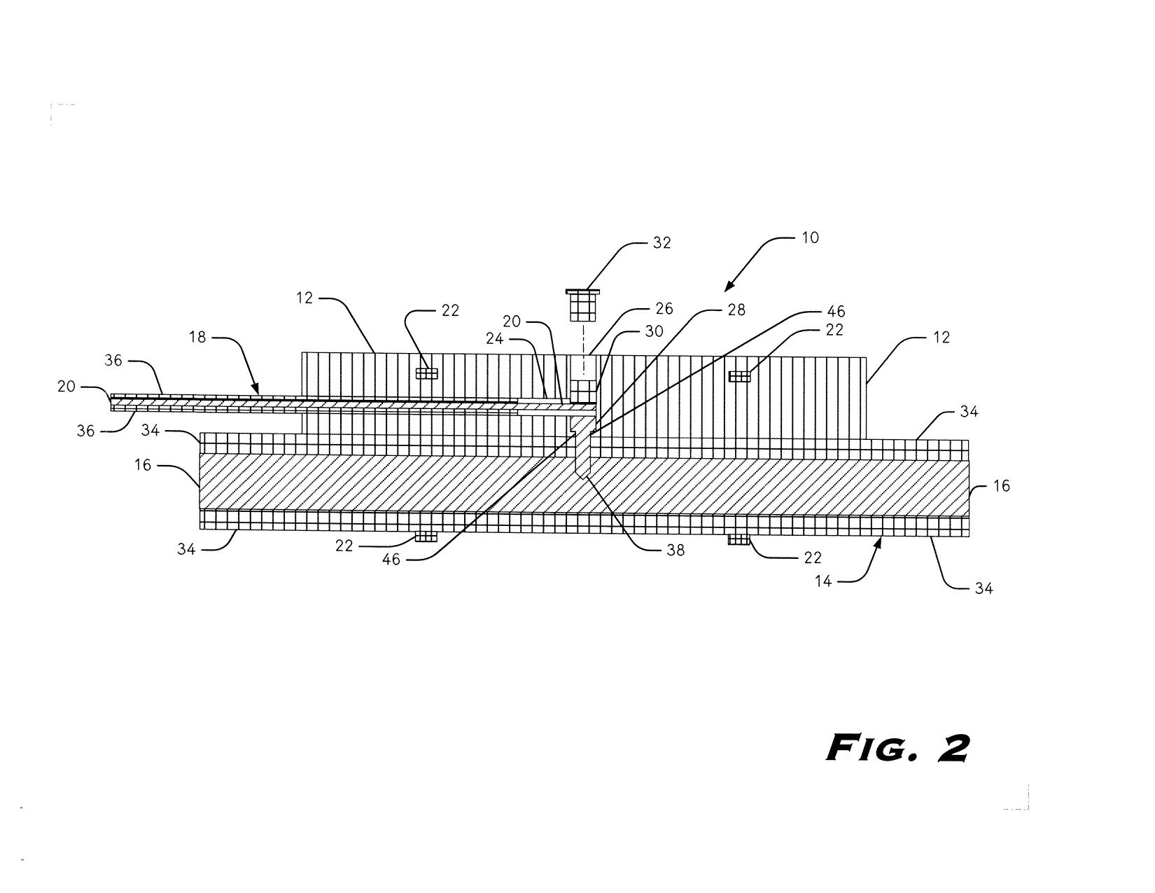

Referring now to both FIGS. 1 and 2, prior to the insertion of thin lead 18 into hole 24 but after the attaching of cable 14 to enclosure using cable ties 22 or an alternate means for attachment, a conductive piercing device such as a conductive screw 28 with a piercing tip 38 is inserted into hole 26. Conductive screw 28 is threaded in some embodiments, as is a threaded extension 46 of hole 26. Piercing tip 38 penetrates insulation 34 of cable 14 and becomes embedded in thick conductive wire 16 when conductive screw 28 is rotated in a tightening direction. Aside from providing a conducting means from thin conductive wire 20 to thick conductive wire 16, conductive screw 28 also serves as a secondary securing means to secure cable 14 to enclosure 12.

After conductive screw 28 is tightened, thin lead 18 (from which a length of insulation 36 has been stripped to expose a portion of thin conductive wire 20) is inserted into hole 24 so that a portion of thin conductive wire 20 (i.e., the stripped end of thin lead 18) is directly over conductive screw 28 internal to enclosure 12. A set screw 30 is inserted above thin conductive wire 20 and conductive screw 28 in hole 26. Set screw 30 is tightened to compressively secure thin conductive wire 20 to conductive screw 28, ensuring that a tight connection is made. In embodiments in which setscrew 30 is conductive, an optional cap screw 32 of an insulating material may be installed above setscrew 30. In some embodiments, instead of a setscrew 30, a spring and pressure plate (not shown) is used to hold thin conductive wire 20 down on conductive screw 28.

Some embodiments include an O-ring or bushing around the outside or in the inside of hole 24 to keep moisture and/or foreign matter away from the electrical connection formed between conductive screw 28 and thin conductive wire 20.

Some embodiments provide a piercing probe (not shown) as a conductive piercing device that is part of, attached to, embedded within or molded into enclosure 12. The piercing probe in these embodiments is configured so that when enclosure 12 is attached to cable 14, it slices through insulation 34 to reach thick conductive wire 16. In some of these embodiments, setscrew 30 is used to secure thin conductive wire 20 to the piercing probe.

In some embodiments in which further protection is needed and referring to FIG. 3, after setscrew 30 is installed, an outer wrapping 39 is wrapped around the assembly. In the illustrated embodiment, outer wrapping 39 is a nonconductive tape, such as electrical tape. In some other embodiments, a protective coating is sprayed or brushed on to form a protective encapsulation.

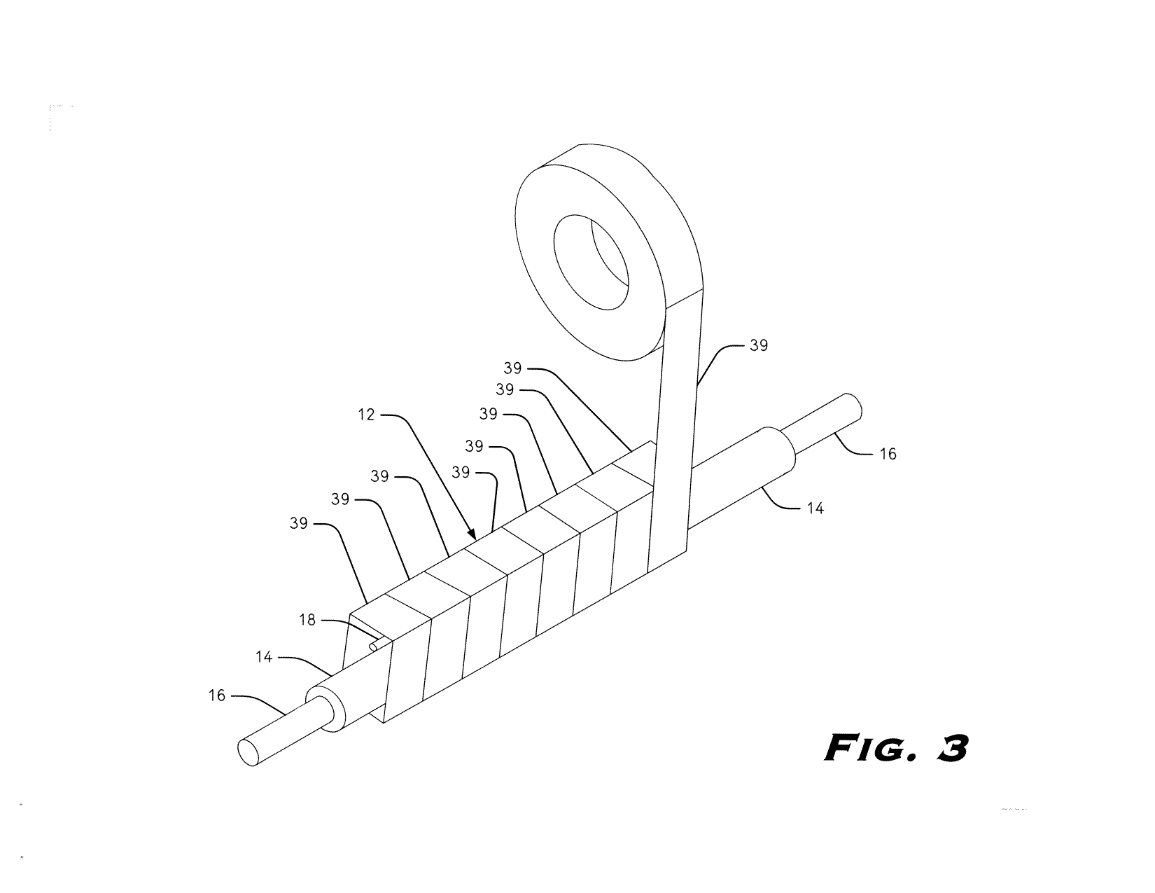

In some embodiments and referring to FIG. 4, ridges 40 are provided on the arcuate side of enclosure 12 that is in contact with cable 14. Ridges 40 penetrate or at least compress insulation 34, thereby forming a seal around a hole in cable 14 that is made by the conductive penetrating device or conductive screw.

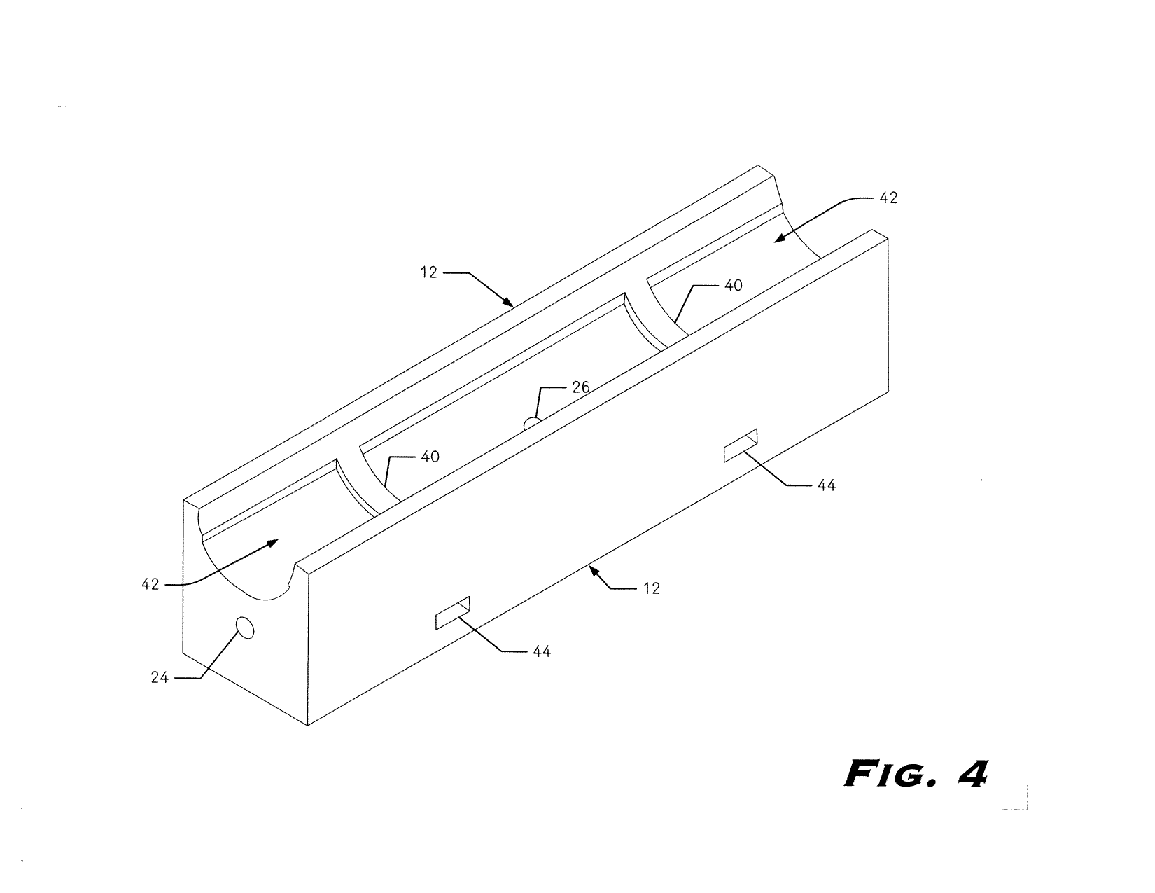

In some embodiments and referring to FIG. 1, one or more cable ties 22 are used to secure enclosure 12 to cable 14, which is held in place in an arcuate groove 42 on one side of enclosure 12. In some embodiments that use cable ties 22 for this purpose and referring to FIGS. 5 and 6, a slot 44 is incorporated into enclosure 12 to allow cable ties 22 to rest flush with enclosure 12 or to be at least partially hidden. In some embodiments, cable ties 22 or other attachment means are made an integral part of enclosure 12. For example, in some embodiments, cable ties 22 are molded into enclosure 12. In other embodiments, enclosure 12 is attached to cable 14 using tapes, glues, metal bands, and/or straps.

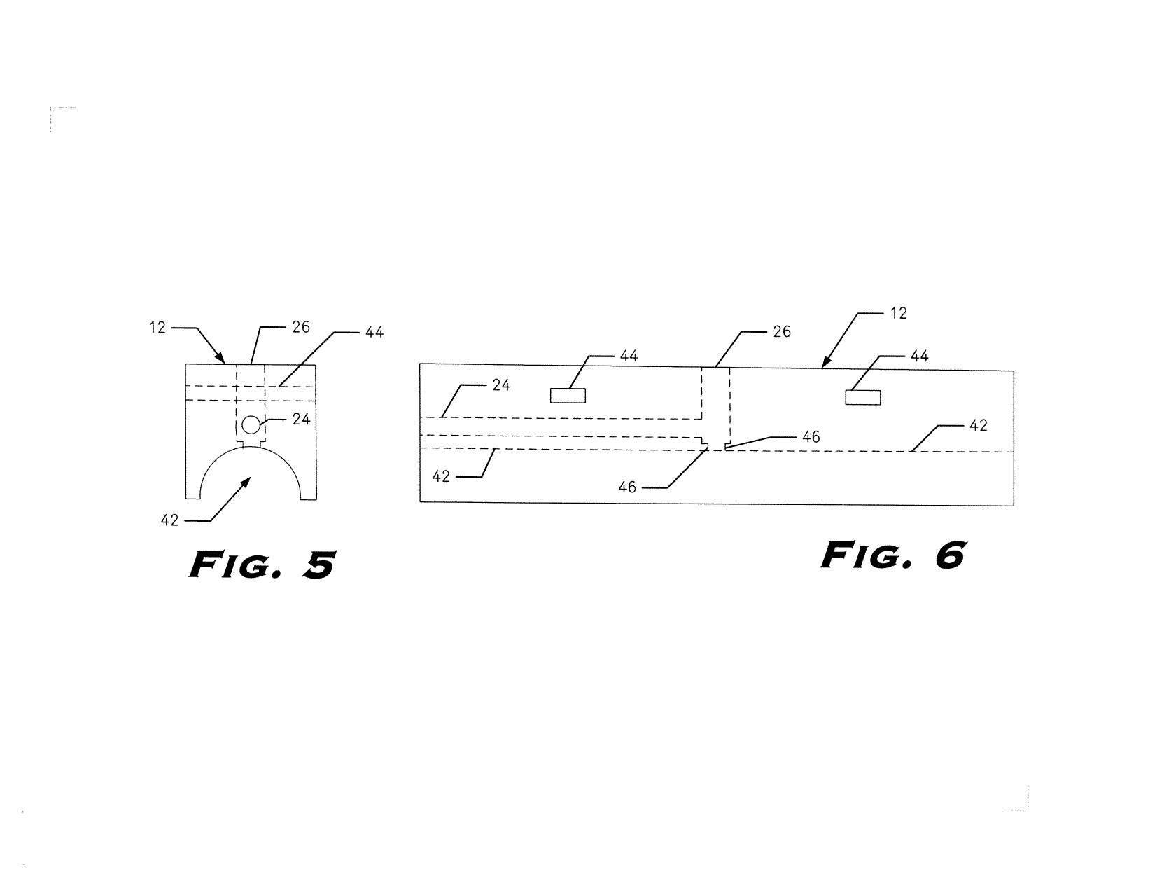

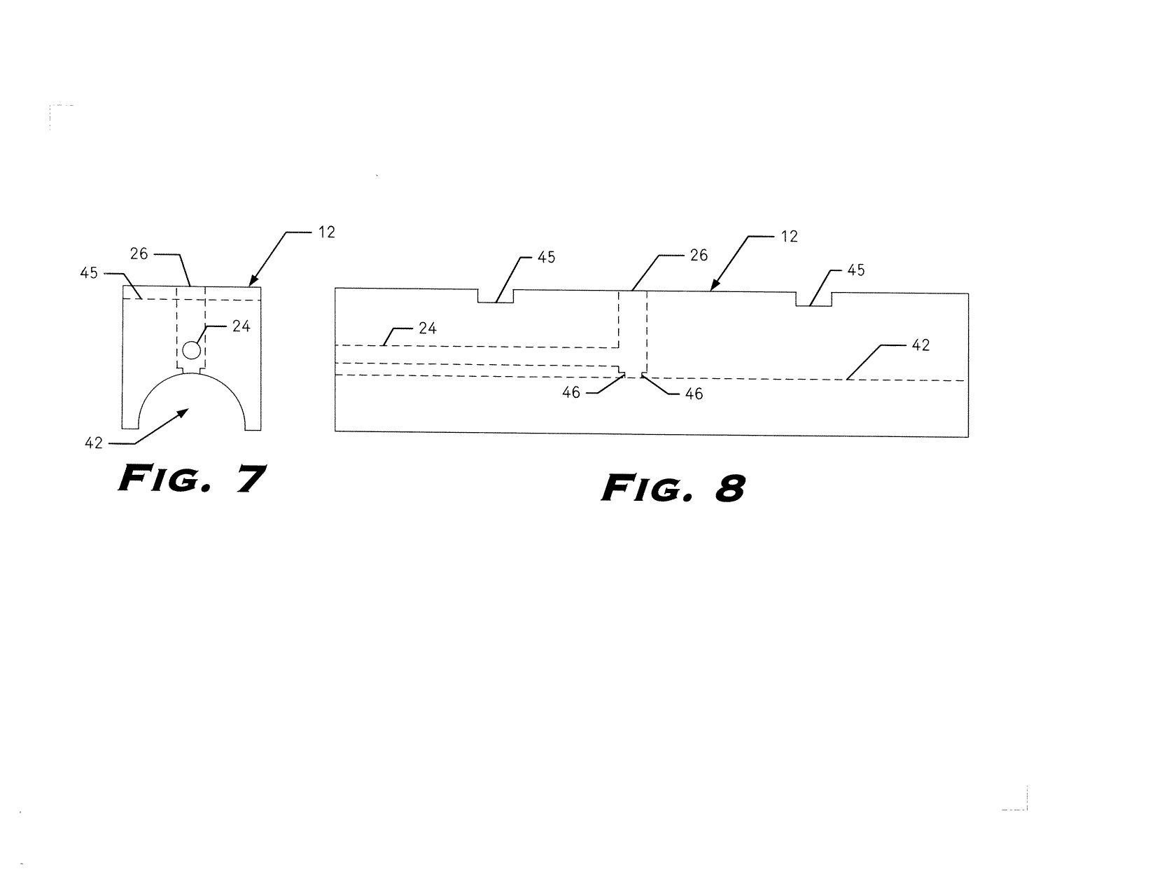

In some embodiments and referring to FIGS. 7 and 8, a groove or grooves 45 are used to allow cable ties 22 to rest flush or nearly flush with enclosure 12, to hold cable ties 22 in place, and/or to allow cable ties 22 to be at least partially recessed as compared to where they would rest without groove or grooves 45.

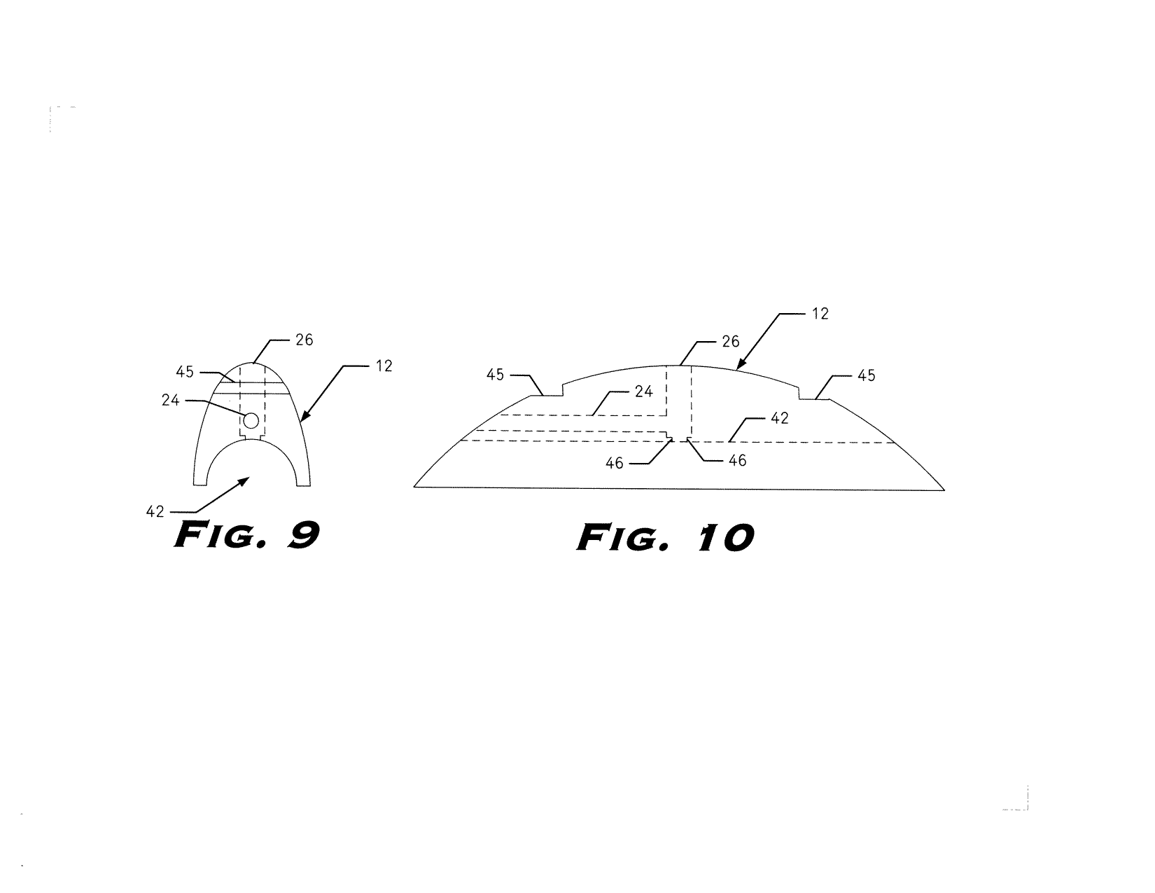

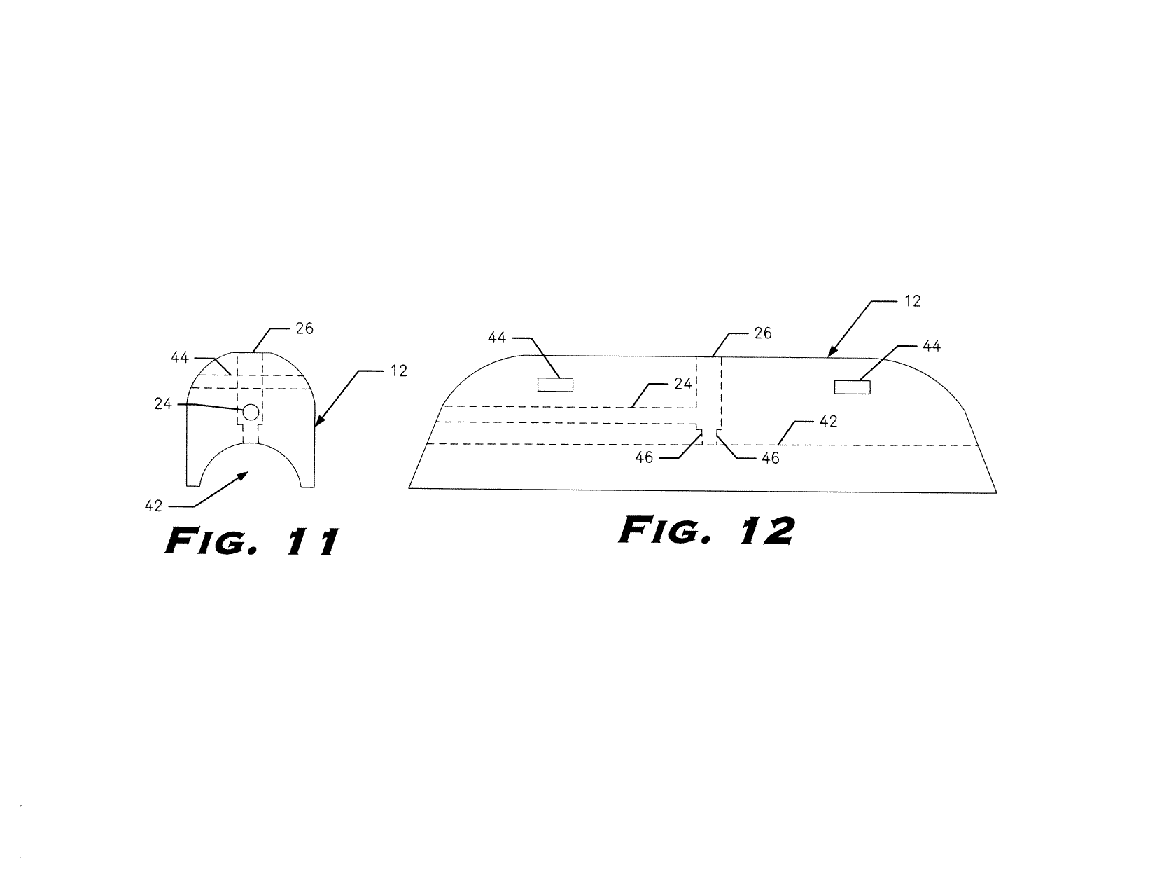

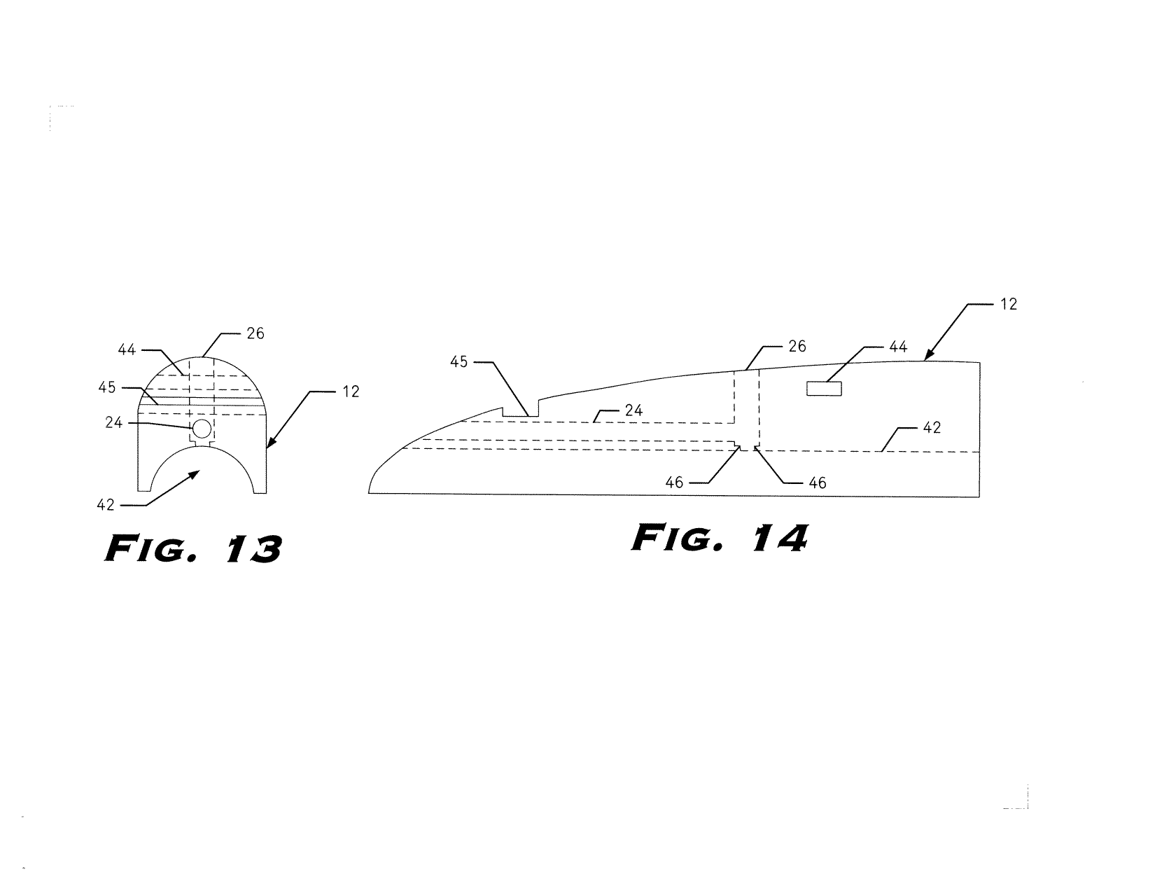

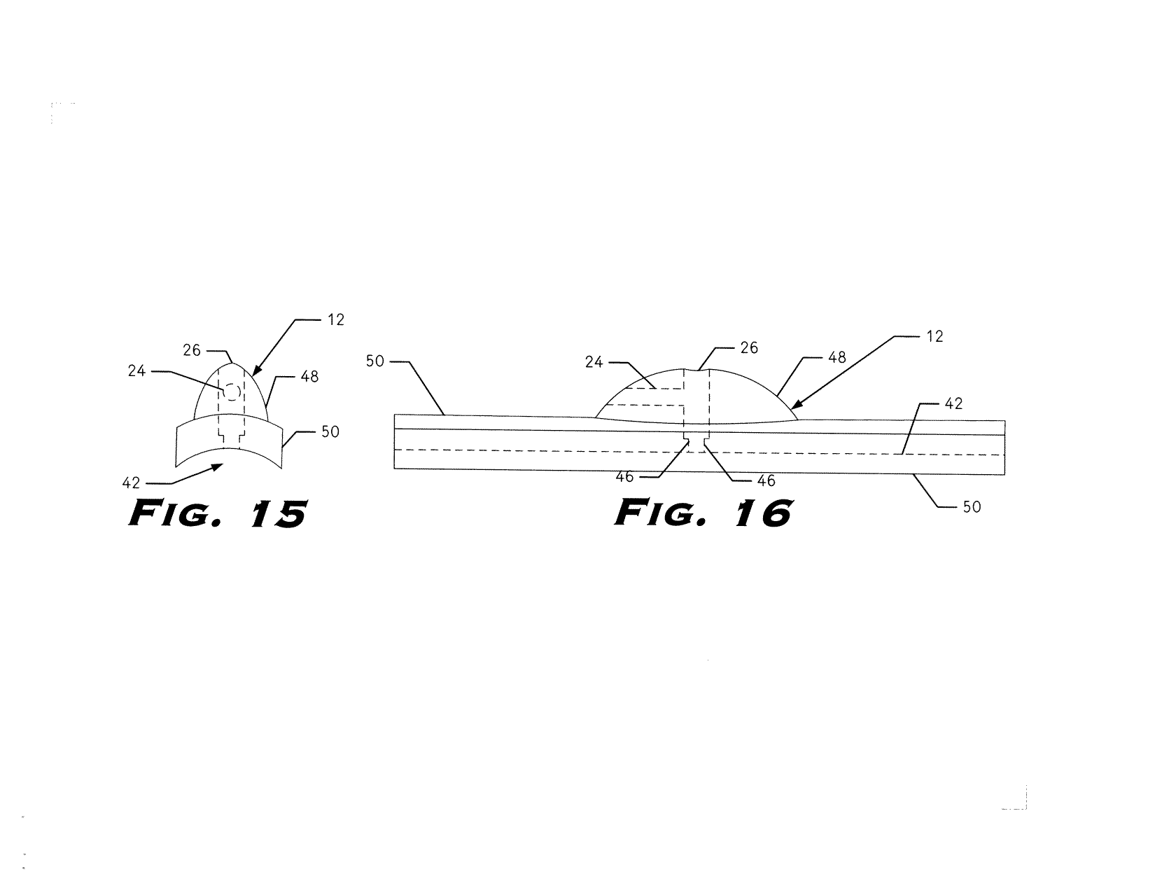

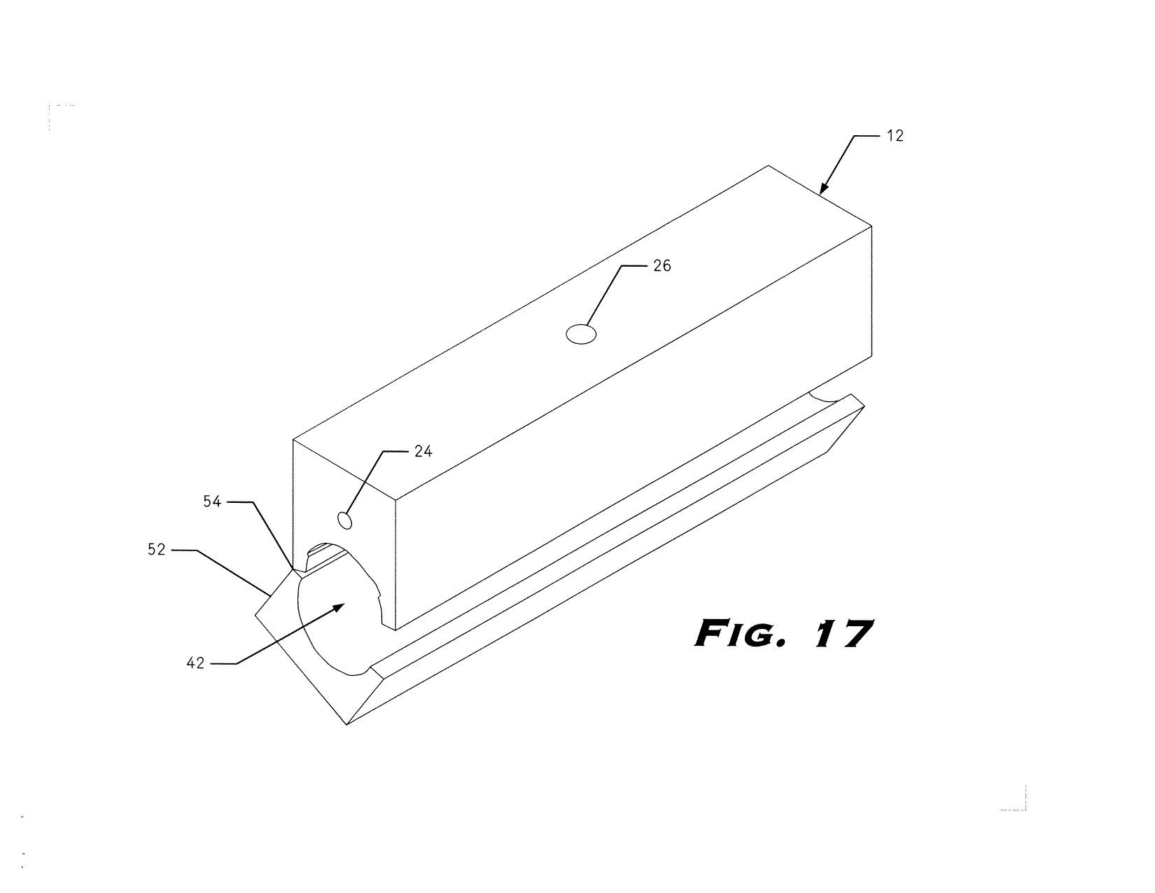

Although some embodiments of enclosure 12 have substantially rectangular cross section (except for arcuate groove 42), a substantially rectangular cross section is not a requirement to practice the present invention. For example, and referring to the example embodiments shown in FIGS. 9 and 10, FIGS. 11 and 12, FIGS. 13 and 14, and FIGS. 15 and 16, various faces of enclosure 12 are curved in some embodiments. In some embodiments and referring to FIGS. 15 and 16, different cable sizes are accommodated by providing variously sized, separately selectable inserts 50 that mate with a universal top fitting 48. The variously sized inserts 50 provide different arcuate groove 42 sizes that match different cable 14 sizes. In some other embodiments, enclosure 12 (or insert 50) comprises a form-fitting material (at least on a surface of enclosure 12 or insert 50) that compressively takes the shape of the contour of cable 14 fitted in arcuate groove 42.

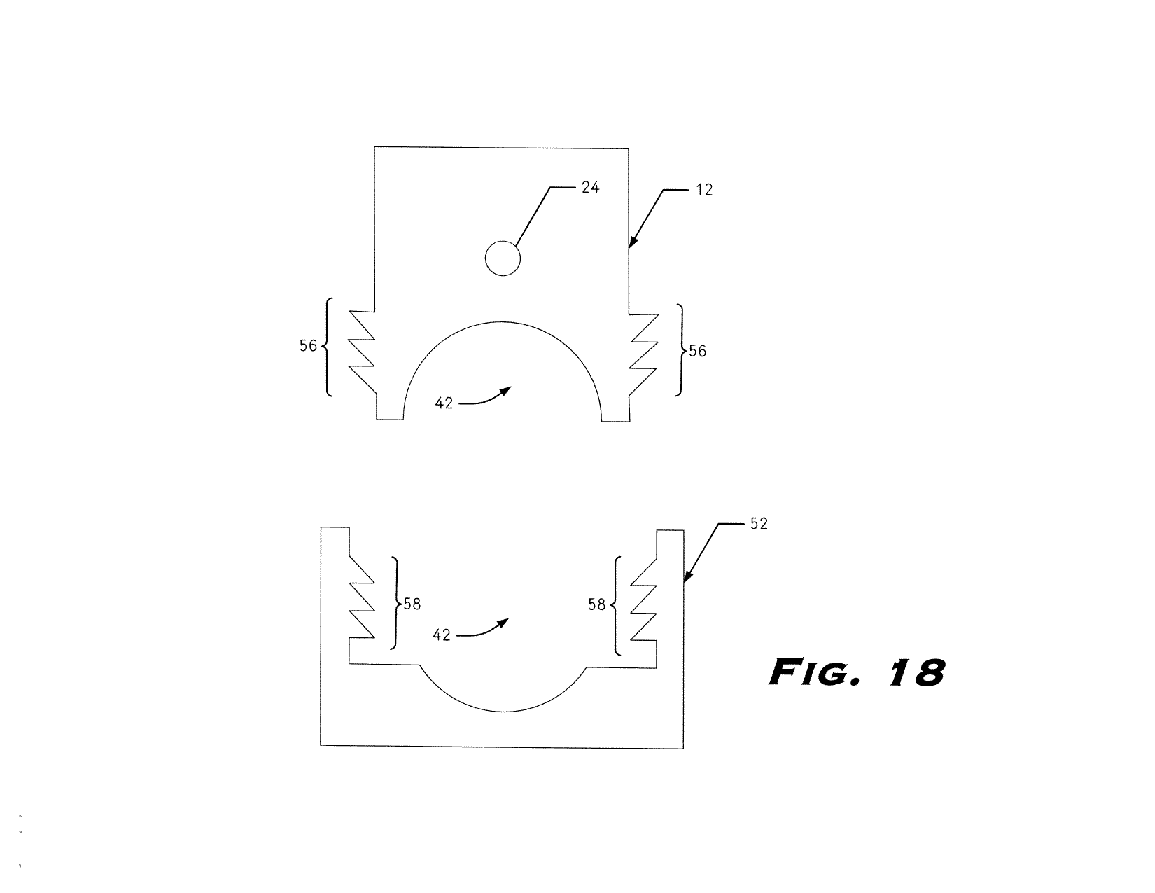

In some embodiments and referring to FIG. 17, a second cover piece 52 is hinged at an edge 54 common to cover piece 52 and enclosure 12. For example, enclosure 12 and a cover piece 52 are molded from a single piece of flexible plastic with a thin, pliable edge 54 in common. After a cable 14 is placed within groove 42, the pliable edge 54 is bent so that cable 14 is held in place between enclosure 12 and cover piece 52. In at least one such embodiment, cover piece 52 and enclosure 12 are taped together in a manner similar to that shown in FIG. 3 after being electrically connected in a manner similar to that shown in FIG. 2.

In yet another embodiment and referring to FIG. 18, cover piece 52 is separate from enclosure 12. A cable 14 is placed in a channel 42 of either cover piece 52 or enclosure 12. Cover piece 52 is then pushed onto enclosure 12 with cable 14 enclosed between. Cover piece 52 uses a series of ratcheting teeth 58 that snap into place when pushed over a corresponding series of ratcheting teeth 56 on enclosure 12 to maintain a tight grip of cover piece 52 and enclosure 12 around cable 14. Cable 14 is then connected to a thin lead 18 (neither of which are shown in FIG. 18) in a manner similar to that shown in FIG. 2.

It will thus be appreciated that some embodiments of the present invention provide methods and apparatus for splicing a small gage wire to a much larger cable that can be used by an individual having no knowledge or skills in dealing with electrical wiring. In addition, it will be appreciated that some embodiments of the present invention provide methods and apparatus that permit the installation of splices by a lay person with readily available tools, such as a screwdriver. Moreover, some embodiments of the present invention provide a splice apparatus that can include parts molded out of plastic or hard rubber (or another inexpensive insulating material) and other very inexpensive metal parts, such as screws and bushings. This, some embodiments of the present invention are very cost effective even if manufactured on a small scale.

While the invention has been described in terms of various specific embodiments, those skilled in the art will recognize that the invention can be practiced with modification within the spirit and scope of the claims.

What is claimed is:

1. A splice enclosure comprising a non-conductive material, said splice enclosure having an arcuate groove configured to accept a cable, a first hole configured to hold a conductive piercing device therein, and a second hole configured to accept a thin lead having a stripped end so that said stripped end of said thin lead can be compressively held over said conductive piercing device to create an electrical contact between said cable and said thin lead.

2. The enclosure of claim 1 wherein said conductive piercing device comprises a piercing probe embedded in or molded into said enclosure.

3. The enclosure of claim 1 wherein said conductive piercing device comprises a conductive screw.

4. The enclosure of claim 3 wherein said first hole comprises a threaded extension for said conductive screw.

5. The enclosure of claim 1 further comprising a setscrew to compressively secure said stripped end of said thin lead over said conductive piercing device.

6. The enclosure of claim 1 further comprising at least one of an O-ring and a bushing outside or inside of said second hole to keep moisture, foreign matter, or both away from an electrical connection between said conductive piercing device and said stripped thin lead.

7. The enclosure of claim 1 wherein said arcuate groove includes ridges configured to penetrate or compress insulation on the cable to thereby form a seal around a hole in the cable made by said piercing device.

8. The enclosure of claim 1 further comprising at least one cable tie configured to secure said enclosure to the cable.

9. The enclosure of claim 8 wherein said enclosure includes at least one slot in which to rest said at least one cable tie.

10. The enclosure of claim 8 wherein said enclosure includes at least one groove in which to rest said at least one cable tie.

11. The enclosure of claim 1 and a cover piece hinged at an edge common to said cover piece and said enclosure, said cover piece configured to hold the cable between said enclosure and said cover piece.

12. The enclosure of claim 1 and a cover piece separate from said enclosure, said cover piece and said enclosure having a corresponding series of ratcheting teeth configured so that said cover piece and said enclosure maintain a tight grip on the cable when said cover piece is pushed over said enclosure with the cable between.

13. The enclosure of claim 1 wherein said enclosure comprises a universal top fitting and a separately selectable insert to match a size of the cable.

14. The enclosure of claim 1 wherein said enclosure further comprises a form-fitting material that compressively takes a shape of a contour of the cable in said arcuate groove.

15. A method for electrically splicing a cable to a thin lead, said method comprising:
attaching a cable to an enclosure having a conductive piercing device;
stripping a length of insulation from an end of the thin lead to expose a portion of thin conductive wire;
inserting the stripped end of the thin lead into a hole in the enclosure so that at least a portion of the thin conductive wire is directly over the conductive piercing device internal to the enclosure; and
compressively securing the thin conductive wire to the conductive piercing device.

16. The method of claim 15 wherein said attaching a cable to an enclosure comprises wrapping at least one cable tie around the enclosure and the cable.

17. The method of claim 15 wherein said attaching a cable to an enclosure having a conductive piercing device further comprises piercing the cable with a conductive screw having a piercing tip.

18. The method of claim 17 wherein said compressively securing the thin conductive wire to the conductive piercing device further comprises tightening a setscrew.

19. The method of claim 18 further comprising placing a cap screw about the setscrew.

20. The method of claim 15 wherein said attaching a cable to the enclosure further comprises wrapping the cable and the enclosure in a nonconductive tape.

21. The method of claim 15 wherein said attaching a cable to the enclosure further comprises compressing the cable between the enclosure and a cover piece.
